(19) United States
(12) Patent Application Publication
(10) Pub. No.: US 2012/0199201 A1
(43) Pub. Date: Aug. 9, 2012

(54) ORGANIC THIN FILM SOLAR CELL AND MANUFACTURING METHOD THEREOF

(76) Inventors: Takahiro Seike, Ibaraki (JP); Toshihiro Ohnishi, Ibaraki (JP)

(21) Appl. No.: 13/503,054

(22) PCT Filed: Oct. 22, 2010
(86) PCT No.: PCT/JP2010/068733

§ 371 Date: Apr. 20, 2012

(30) Foreign Application Priority Data
Oct. 30, 2009 (JP) 2009-251249

(51) Int. Cl. H01L 51/44; H01L 51/48

(52) U.S. Cl. 136/259; 438/64; 257/E51.012

(57) ABSTRACT

An organic thin film solar cell including: a pair of electrodes of a first electrode (32) and a second electrode (34); an active layer (50) placed between the pair of electrodes; an insulation film stacked substrate (10) including a substrate (12) containing a metal or an alloy having heat conductivity higher than 10 W/m.K and lower than 500 W/m.K and an insulation film (14) provided on the substrate; and a sealing layer (60) placed between the insulation film of the insulation film stacked substrate and either one of the pair of electrodes, suppresses deterioration of electrical properties.

### TECHNICAL FIELD

The present invention relates to an organic thin film solar cell and a method for manufacturing the organic thin film solar cell.

### BACKGROUND ART

An organic thin film solar cell comprises a pair of electrodes and an active layer sandwiched between a pair of electrodes. Specifically for an electrode that is arranged opposing to a transparent substrate and the other transparent electrode from which light enters, an Al electrode made of aluminum (Al) excellent in electric properties such as a low work function and high electric conductivity is used in many cases.

However, the Al electrode tends to become eroded due to moisture and oxygen in the external environment (atmosphere), and as the result, electric properties of the organic thin film solar cell such as photovoltaic conversion efficiency may be deteriorated in some cases. In addition, when a sealing layer is formed on the Al electrode, heat dissipation may be decreased and thus photovoltaic conversion efficiency may be decreased in some cases.

To solve the problems described above such as deterioration of electrodes and a decrease in photovoltaic conversion efficiency due to the deterioration of electrodes, various solutions have been studied. For example, an organic electroluminescent element is known, in which an insulation layer made of germanium oxide is provided on an Al electrode that is an anode and further a sealing layer covering the insulation layer with an aluminum film is provided(refer to Patent literature 1).

### RELATED ART DOCUMENTS

Patent Document 1:JP 2001-185348 A

### DISCLOSURE OF INVENTION

### Problem to be Solved by the Invention

However, in the organic thin film solar cell that is provided with a conventional structure, heat dissipation is insufficient. Also, in the structure of the organic electroluminescent element of the above patent document, because, for forming an sealing layer, an insulation layer is stacked directly on an Al electrode and then a metal film is stacked on the insulation layer, conduction between an Al electrode and a metal film may be caused at a defect site inevitably generated on the insulation layer in some cases.

In this way, when conduction between an Al electrode and a metal film exposed to an external environment is caused due to a defect site of the insulation film and the metal film exposed to an external environment is connected with the electrode through the defect site of the insulation film, the electrode may be easily eroded (deteriorated) from the defect site of the insulation film and impairing electric properties of the element as well as deteriorating the active layer due to deterioration of the electrode may be caused. As the result, the photovoltaic conversion efficiency is decreased in some cases.

The inventors of the present invention have proceeded with their studies intensively, and they have found that the above mentioned problems can be solved by adopting an insulation film stacked substrate in which an insulation film is stacked on a substrate comprising a metal or an alloy, thereby completed the present invention.

The present invention provides an organic thin film solar cell and a method for manufacturing thereof as described below.

[1] An organic thin film solar cell comprising:

a pair of electrodes of a first electrode and a second electrode;

an active layer placed between the pair of electrodes;

an insulation film stacked substrate comprising, a substrate comprising a metal or an alloy having heat conductivity higher than 10 W/m.K and lower than 500 W/m.K, and an insulation film provided on the substrate; and a sealing layer placed between the insulation film of the insulation film stacked substrate and either one of the pair of electrodes.

[2] An organic thin film solar cell comprising:

a pair of electrodes of a first electrode and a second electrode;

an active layer placed between the pair of electrodes; and

an insulation film stacked substrate comprising, a substrate comprising a metal or an alloy having heat conductivity higher than 10 W/m.K and lower than 500 W/m.K, and an insulation film provided with the substrate, the insulation film being provided adjacent to either of the pair of electrodes.

[3] The organic thin film solar cell according to [1] or [2], wherein the metal is aluminum or copper.
[4] The organic thin film solar cell according to [1] or [2], wherein the alloy is stainless steel.
[5] The organic thin film solar cell according to any one of [1] to [4], wherein the insulation film is composed of an insulative inorganic compound or an insulative organic compound.

[6] The organic thin film solar cell according to [5], wherein the insulative inorganic compound is an oxide, a nitride, or a carbide.

[7] The organic thin film solar cell according to [5] or [6], wherein the insulative inorganic compound is one selected from the group consisting of silicon, aluminum, and zirconium.
[8] The organic thin film solar cell according to [5], wherein the insulative organic compound is polyimide.
[9] The organic thin film solar cell according to any one of [1] to [8], wherein the insulation film stacked substrate is a supporting substrate.
[10] The organic thin film solar cell according to any one of [1] to [8], wherein the insulation film stacked substrate is a sealing substrate.
[11] A method for manufacturing an organic thin film solar cell, the method comprising the steps of:

preparing an insulation film stacked substrate comprising, a substrate comprising a metal or an alloy, and an insulation film formed on the substrate;

forming a first electrode on a supporting substrate;

forming a first electrical charge transport layer on the substrate on which the first electrode is formed;

forming an active layer on the first electrical charge transport layer;

forming a second electrical charge transport layer on the active layer;

forming a second electrode on the second electrical charge transport layer;

forming a sealing layer placed between the second electrode and the insulation film by joining the second electrode to the insulation film of the insulation film stacked substrate by using a sealant.

[12] A method for manufacturing an organic thin film solar cell, the method comprising the steps of:

preparing an insulation film stacked substrate comprising, a substrate comprising a metal or an alloy, and an insulation film formed on the substrate;

forming a first electrode on the insulation film of the insulation film stacked substrate;

forming a first electrical charge transport layer on the insulation film stacked substrate on which the first electrode is formed;

forming an active layer on the first electrical charge transport layer;

forming a second electrical charge transport layer on the active layer;
forming a second electrode on the second electrical charge transport layer; and
forming a sealing layer placed between the second electrode and a sealing substrate by joining the second electrode to the sealing substrate by using a sealant.

### BRIEF DESCRIPTION OF DRAWINGS

FIG. 1 is a schematic cross sectional view illustrating a structure of an insulation film stacked substrate.

FIG. 2 is a schematic cross sectional view illustrating an example of a structure of an organic thin film solar cell of a first embodiment.

FIG. 3 is a schematic cross sectional view illustrating an example of a structure of an organic thin film solar cell of a second embodiment.

### EXPLANATIONS OF LETTERS OR NUMERALS

10: insulation film stacked substrate
12: substrate
14: insulation film
20: supporting substrate, sealing substrate
32: first electrode
34: second electrode
42: first electrical charge transport layer
44: second electrical charge transport layer
50: active layer
60: sealing layer (sealant, adhesive)

### DESCRIPTION OF EMBODIMENTS

Hereafter, the present invention is explained in detail referring to the Figures. In the following explanation, respective Figures simply illustrate an outline of a shape, a size, and an arrangement to the extent that the present invention is understood, and therefore the present invention is not limited to this. In addition, respective Figures have same letters or numbers with respect to the same components, and repeating descriptions may be omitted.

An organic thin film solar cell of the present invention has a pair of electrodes of a first electrode and a second electrode, an active layer placed by the pair of electrodes, a substrate comprising a metal or an alloy, and an insulation film stacked substrate provided with an insulation film on the substrate.

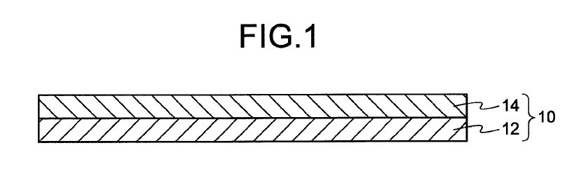

First, with respect to an insulation film stacked substrate as a main component of the organic thin film solar cell of the present invention, the explanation is given referring to FIG. 1. FIG. 1 is a schematic cross sectional view illustrating a structure of an insulation film stacked substrate.

As illustrated in FIG. 1, an insulation film stacked substrate 10 comprises a substrate 12 and an insulation film 14 stacked on the substrate 12. The substrate 12 comprises a metal or an alloy as a material, and, for example, is a parallel-plate state of substrate (thin film) having two-sides of primary surfaces facing each other.

As a metal or an alloy used for the substrate 12, the metal or the alloy having a heat conductivity at 300 K (Kelvin) (hereinafter “heat conductivity” represents a value at 300 K) of more than 10 W/m.K and less than 500 W/m.K are used.

A metal or an alloy included in the substrate 12 has a heat conductivity of, preferably at least 200 W/m.K, and more preferably at least 400 W/m.K.

Examples of the metal material for the substrate 12 may include, preferably aluminum (237 W/m.K), copper (402 W/m.K), silver (430 W/m.K), and gold (327W/m.K). Examples of the alloy material for the substrate 12 may include preferably stainless steel. These metal materials or alloy materials have 10 times or more heat conductivity at 300K compared with the material generally used as a substrate such as a glass. Therefore, by using these for the metal material and the alloy material, heat generated in the cell can be transferred efficiently to an external environment for heat radiation, and thus the cell can be efficiently cooled.

An insulation film 14 comprises an insulative inorganic compound or an insulative organic compound, usually. As the insulative inorganic compound, an inorganic compound comprising any element selected from the group consisting of silicon, aluminum, and zirconium is preferably included. The insulative inorganic compound may be preferably an oxide, a nitride, or a carbide. For example, when comprising silicon, SiO₂ is included as an oxide for the insulative inorganic compound, SiN is included as a nitride for the insulative inorganic compound, and SiC is included as a carbide for the insulative inorganic compound.

For the insulation film 14 of the first embodiment, any high temperature process such as evaporation after forming a sealing layer 60 (adhesion of the insulation film stacked substrate 10) is not required, and therefore heat resistance property is not required.

As the insulative organic compound, the following may be used: a polyimide resin such as polyimide resin and polyimide fluoride resin; a fluorine resin such as tetrafluoroethylene resin, tetrafluoroethylene/perfluoro(alkyl vinyl ether) copolymer resin, tetrafluoroethylene/hexafluoroprpylene copolymer resin, vinylidene fluoride resin, chlorotrifluoroethylene resin and vinylfluoride resin; modified polyphenyleneether; and allylated polyphenylene ether. Among them, a polyimide resin having high heat resistance and electrical insulation property is preferably used.

### First Embodiment

<Organic thin film solar cell>

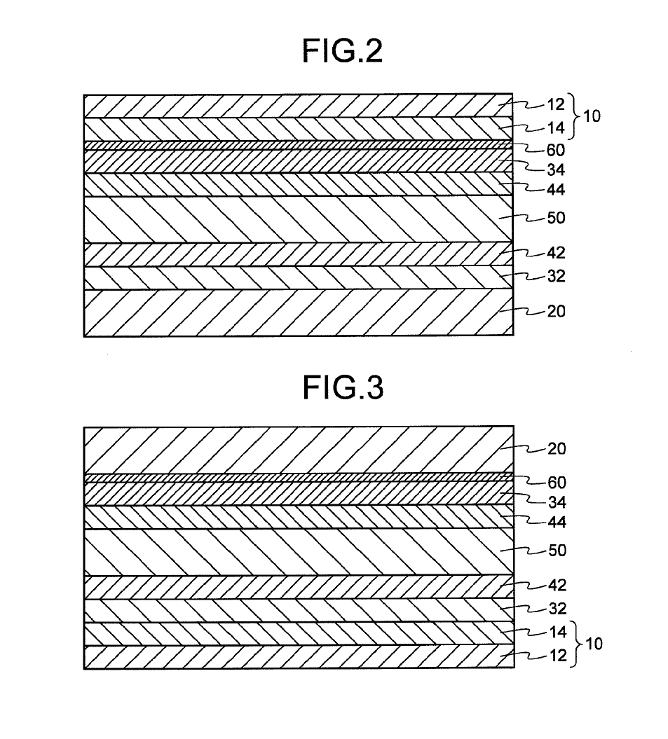

The organic thin film solar cell of a first embodiment is explained referring to FIG. 2. FIG. 2 is a schematic cross sectional view illustrating an example of a structure of an organic thin film solar cell of a first embodiment.

The organic thin film solar cell of the first embodiment is an example of a structure in which an insulation film stacked substrate 10 is made as a sealing substrate.

As illustrated in FIG. 2, the organic thin film solar cell comprises a pair of electrodes of a first electrode 32 and a second electrode 34, an active layer 50 placed between the pair of electrodes, a substrate 12 comprising a metal or an alloy having a heat conductivity of more than 10 W/m.K and smaller than 500 W/m.K, an insulation film stacked substrate 10 comprising an insulation film 14 placed on the substrate, and a sealing layer 60 placed between either of the pair of electrodes and the insulation film 14 of insulation film stacked substrate 10.

At least one electrode, that is one of the pair of electrodes and exists at a side from which light enters, is a transparent or translucent electrode through which incident light (solar light) having a desired wavelength can pass.

Polarities of the first electrode 32 and the second electrode 34 may be an appropriate polarity that is selected arbitrarily corresponding to a structure of the cell, and therefore it may be that the first electrode 32 is a cathode and the second electrode 34 is an anode.

As the transparent or translucent electrodes, an electrically conductive metallic oxide film, a translucent metallic thin film and the like are included. Specifically, a film made of an electrically conductive material such as indium oxide, zinc oxide, tin oxide and a complex thereof such as indium tin oxide (ITO) and indium zinc oxide (IZO); or a film of NESA and the like, gold, platinum, silver, and copper, are used. Among them, a film made of ITO, IZO, or tin oxide is preferred. As a preparing method of an electrode, vacuum evaporation, sputtering, ion plating, and plating are included. Also, as an electrode, an organic transparent electro conductive film of such as polyaniline or a derivative thereof, and polythiophene or a derivative thereof may be used.

As an electrode material for a nontransparent electrode, a metal, an electrically conductive macromolecule compound and the like may be used. Specific examples may include: a metal such as lithium, sodium, potassium, rubidium, cesium, magnesium, calcium, strontium, barium, aluminum, scandium, vanadium, zinc, yttrium, indium, cerium, samarium, europium, terbium and ytterbium; and an alloy of two or more of theses metals; an alloy of one or more types of the metals above and one or more types of metals selected from the group consisting of gold, silver, platinum, copper, manganese, titanium, cobalt, nickel, tungsten and tin; a graphite; a graphite intercalation compound; polyaniline and a derivative thereof; and polythiophene and a derivative thereof. The alloy may be magnesium-silver alloy, magnesium-indium alloy, magnesium-aluminum alloy, indium-silver alloy, lithium-aluminum alloy, lithium-magnesium alloy, lithium-indium alloy, calcium-aluminum alloy, or the like.

An organic thin film solar cell is usually formed on a substrate. That is, a layered structure comprising the first electrode 32, the active layer 50, and the second electrode 34 is provided on a primary surface of supporting substrate 20.

A material for the supporting substrate 20 may be anything, as long as the material that can be provided with an electrode and will not be chemically changed during forming a layer comprising an organic compound. Examples of a material for the supporting substrate 20 may include a glass, a plastic, a macromolecule film, and silicon.

The insulation film stacked substrate 10 is usually nontransparent. Therefore, the supporting substrate 20, which is provided at an opposite side to the insulation film stacked substrate 10 so that the active layer 50 is sandwiched, is usually a transparent substrate.

When the insulation film stacked substrate 10 may be transparent, a non-trasparent substrate may be used for the supporting substrate 20.

The active layer 50 is placed between the first electrode 32 and the second electrode 34. The active layer 50 of the first embodiment is a bulk hetero(junction) type of organic layer (functional layer) in which an electron-acceptor compound (n-type semiconductor) and an electron-donor compound (p-type semiconductor) are mixed and included. The active layer 50 is a layer having a substantial function for photovoltaic function, which can generate electrical charges (hole and electron) by using incident light energy.

The active layer 50 included in the organic thin film solar cell comprises an electron-donor compound and an electron-acceptor compound as described above.

With regard to becoming an electron donor compound or an electron-acceptor compound, it is relatively determined depending on an energy level of the energy level of the compounds, and therefore one compound may become either of an electron-donor compound and an electron-acceptor compound.

Examples of the electron donor compound may include a pyrazoline derivative, an arylamine derivative, a stilbene derivative, a triphenyl diamine derivative, oligothiophene and a derivative thereof, polyvinyl carbazole and a derivative thereof, polysilane and a derivative thereof, a polysiloxane derivative having an aromatic amine at a side chain or a main chain, polyaniline and a derivative thereof, polythiophene and a derivative thereof, polypyrrole and a derivative thereof, polyphenylene vinylene and a derivative thereof, polythienylene vinylene and a derivative thereof.

Examples of the electron-acceptor compound may include an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyl dicyanoethylene and a derivative thereof, a diphenoquinone derivative, 8-hydroxyquinoline and a derivative thereof, polyquinoline and a derivative thereof, polyquinoxaline and a derivative thereof, polyfluorene and a derivative thereof, a fullerene such as C₆₀ fullerene and a derivative thereof, a phenanthrene derivative such as bathocuproin, a metallic oxide such as titanium oxide, and a carbon nanotube. As the electron-acceptor compound, titanium oxide, a carbon nanotube, a fullerene, and a fullerene derivative are preferably included, and more preferably, a fullerene and a fullerene derivative are included.

Examples of a fullerene may include C₆₀ fullerene, C₇₀ fullerene, C₇₆ fullerene, C₇₈ fullerene, and C₈₄ fullerene.

Examples of a fullerene derivative may include respective derivatives of C₆₀ fullerene, C₇₀ fullerene, C₇₆ fullerene, C₇₈ fullerene, and C₈₄ fullerene. Examples of a specific structure of the fullerene derivative are included as follows.

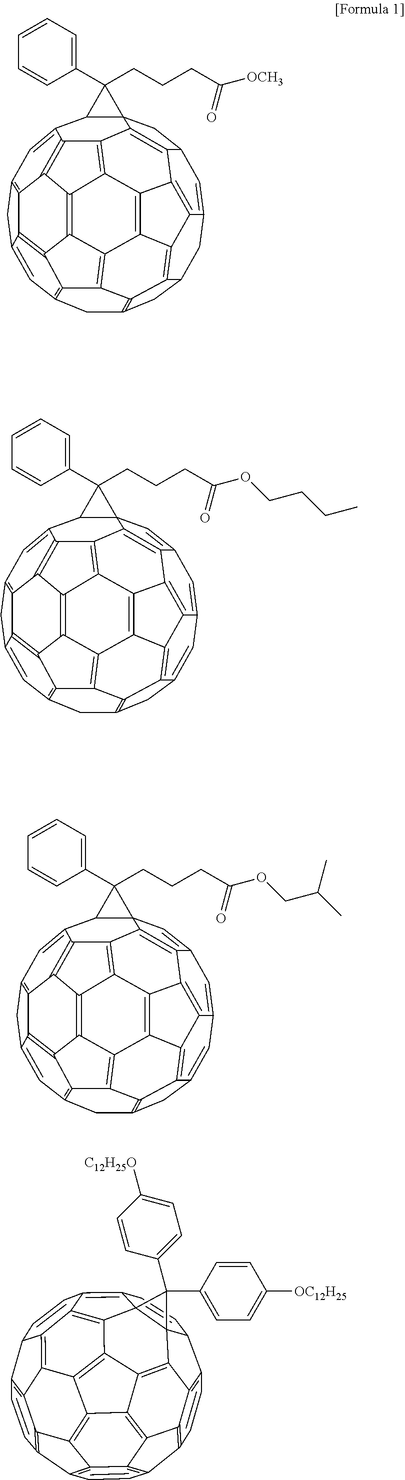

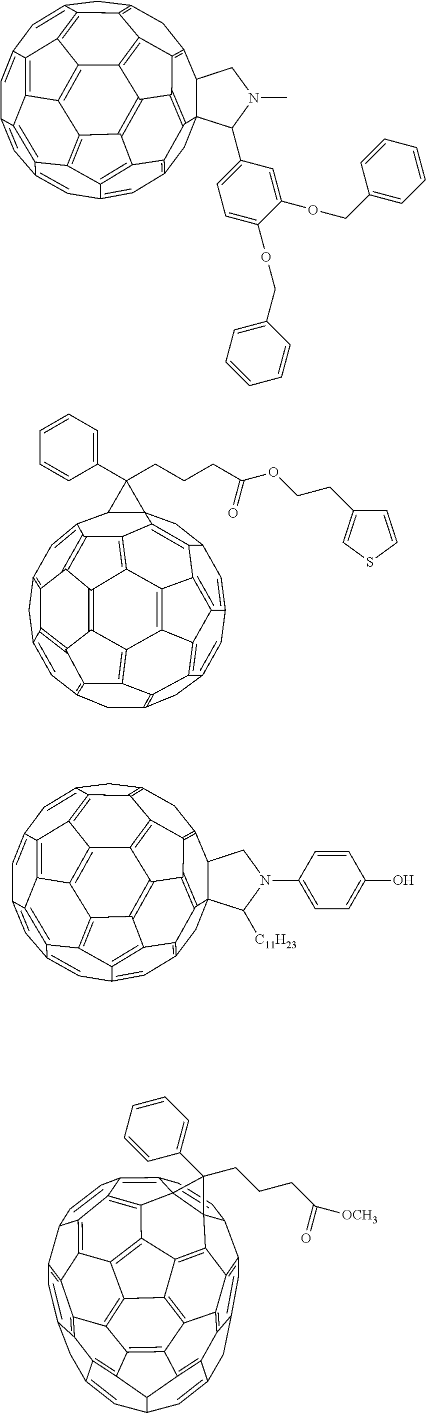

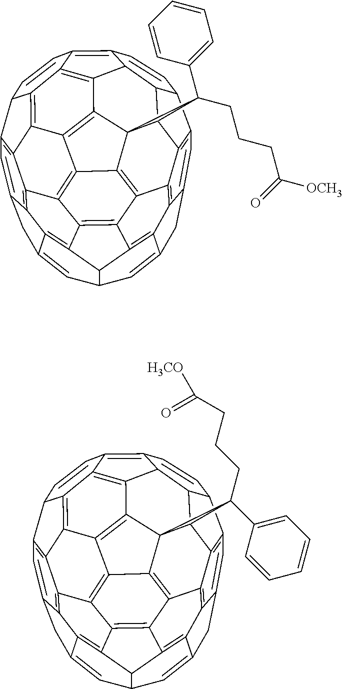

Examples of a fullerene derivative may include

[6,6]phenyl-C₆₁ butyric acid methyl ester (C₆₀ PCBM),
[6,6]phenyl-C₇₁ butyric acid methyl ester (C₇₀ PCBM),
[6,6]phenyl-C₈₅ butyric acid methyl ester (C₈₄ PCBM), and
[6,6]thienyl-C₆₁ butyric acid methyl ester.

When using a fullerene derivative as an electron-acceptor compound, a proportion of the fullerene derivative is preferably 10 to 1000 parts by weight, more preferably 20 to 500 parts by weight, per 100 parts by weight of an electron-donor compound.

A thickness of the active layer 50 is, in general, preferably 1 nm to 100 μm, more preferably 2 nm to 1000 nm, further preferably 5 nm to 500 nm, and in still further preferably 20 nm to 200 nm.

In the first embodiment, the active layer 50 is explained, which is a single layer in which an electron-acceptor compound and an electron-donor compound are mixed up to become a bulk hetero type. Or, the active layer 50 may be a structure comprising multiple layers. For example, it may be a hetero junction type in which an electron-acceptor layer comprising an electron-acceptor compound such as a fullerene derivative and an electron-donor layer comprising an electron-donor compound such as P3HT are joined.

The proportion of an electron-acceptor compound in a bulk hetero type of active layer comprising an electron-acceptor compound and an electron-donor compound is preferably 10 to 1000 parts by weight, more preferably 50 to 500 parts by weight, per 100 parts by weight of an electron-donor compound.

The organic thin film solar cell may comprise an additional intermediate layer other than the active layer between at least either one of the first electrode 32 and the second electrode 34 and the active layer 50 as one means for improving the photovoltaic conversion efficiency. Examples of a material used for the additional intermediate layer may include a halogenated compound of an alkaline metal or an alkali earth metal such as lithium fluoride, and an oxide of an alkaline metal and an alkali earth metal.

Examples of a material for the additional intermediate layer also may include an inorganic semiconductor particulate such as titanium oxide and PEDOT (poly-3,4-ethylenedioxythiophene).

Examples of the additional layer may include an electrical charge transport layer (hole transport layer, electron transport layer) that transports holes or electrons.

As a material for the above electrical charge transport layer, an arbitrary appropriate material may be used. When the electrical charge transport layer is an electron transport layer, as an example of a material, 2,9-dimethyl-4,7-diphenyl-1,10-phenanthroline (BCP) is included. When the electrical charge transport layer is a hole transport layer, a material may be PEDOT.

The additional intermediate layer optionally provided between the first electrode 32 or the second electrode 34 and the active layer 50 may be a buffer layer, and examples of a material for the buffer layer may include a halogenide of an alkaline metal or an alkaline earth metal such as lithium fluoride, and an oxide such as titanium oxide. When an inorganic semiconductor is used, it may be used in a form of particulates.

Some of the examples of a layer structure of an organic photovoltaic cell are as follows:

a) Anode/Active layer/Cathode;
b) Anode/Hole transport layer/Active layer/Cathode;
c) Anode/Active layer/Electron transport layer/ Cathode;
d) Anode/Hole transport layer/Active layer/Electron transport layer/Cathode;
e) Anode/Electron-donor layer/Electron-acceptor layer/Cathode;
f) Anode/Hole transport layer/Electron-donor layer/Electron-acceptor layer/Cathode;
g) Anode/Electron-donor layer/Electron-acceptor layer/Electron transport layer/Cathode; and
h) Anode/Hole transport layer/Electron-donor layer/Electron-acceptor layer/Electron transport layer/Cathode
(the symbol “/” indicates that layers at both sides of the symbol “/” are stacked adjacent to each other.)

The respective above-mentioned layer structures may be a form that an anode is provided closer to the substrate, or a form that a cathode is provided closer to the substrate.

In the above-mentioned layer structures, respective layers may be a single layer, or may be a layered body having two or more layers.

The structure of the organic thin film solar cell is explained, more specifically. The first electrode 32 is provided on a primary surface of the supporting substrate 20.

A first electrical charge transport layer 42 is provided on the first electrode 32. The first electrical charge transport layer 42 is a hole transport layer when the first electrode 32 is an anode, and is an electron transport layer when the first electrode 32 is a cathode.

The active layer 50 is provided on the first electrical charge transport layer 42. A second electrical charge transport layer 44 is provided on the active layer 50. The second electrical charge transport layer 44 is an electron transport layer when the first electrode 32 is an anode, and is a hole transport layer when the first electrode 32 is a cathode. The second electrode 34 is provided on the second electrical charge transport layer 44.

The sealing layer 60 is provided on the second electrode 34. The sealing layer 60 adheres to the insulation film stacked substrate 10. With regard to the insulation film stacked substrate 10, the insulation film 14 thereof is joined to the second electrode 34 through the sealing layer 60, so that the substrate 12 of the insulation film stacked substrate 10 is exposed to an external environment.

In other words, the sealing layer 60 is placed between the insulation film 14 of the insulation film stacked substrate 10 and either one of a pair of electrodes. In the present example of a structure, “either one of electrodes” refers to the second electrode 34. The sealing layer 60 may be formed by using a well-known and appropriate material arbitrarily, taking into consideration adhesiveness, heat resistance, and barrier properties against such as moisture and oxygen. Examples of a material for the sealing layer 60 may include a sealant or an adhesive that are made from an epoxy resin, a silicone resin, an acryl resin, or a methacryl resin.

According to an organic thin film solar cell of the first embodiment, because an insulation film stacked substrate obtained from a material excellent in thermal conductivity and heat dissipation is provided, an increase of the temperature of the organic thin film solar cell can be suppressed. Thus, deterioration in properties of the organic thin film solar cell due to an increase of the temperature of the organic thin film solar cell can be suppressed effectively.

An organic thin film solar cell of the first embodiment is provided with a sealing layer on the second electrode, and the sealing layer joins an insulation film stacked substrate to the second electrode. Therefore, according to this structure, a defect site inevitably generated on the insulation layer is protected by the sealing layer. Thus, because conduction does not occur between the electrode and the substrate of the insulation film stacked substrate, deterioration of the organic thin film solar cell due to such as moisture and oxygen in an external environment can be reduced effectively.

<Manufacturing Method>

A method for manufacturing the organic thin film solar cell is explained referring to FIG. 2.

The method for manufacturing an organic thin film solar cell of the first embodiment is a method for manufacturing the organic thin film solar cell comprising a pair of electrodes of a first electrode and a second electrode 34, and an active layer 50 placed between the pair of electrodes, and the method comprises: preparing an insulation film stacked substrate 10 provided with a substrate 12 comprising a metal or an alloy and an insulation film 14 formed on the substrate 12; forming a first electrode 32 on a supporting substrate 20; forming a first electrical charge transport layer 42 on the supporting substrate 20 provided with the first electrode 32; forming an active layer 50 on the first electrical charge transport layer 42; forming a second electrical charge transport layer 44 on the active layer 50; forming a second electrode 34 on the second electrical charge transport layer 44; and forming a sealing layer 60 placed between the second electrode 34 and the insulation film 14 by joining the second electrode 34 to the insulation film 14 of the insulation film stacked substrate 10 by using a sealant.

For manufacturing the organic thin film solar cell, at first, the insulation film stacked substrate 10 is prepared.

The insulation film stacked substrate 10 is formed by forming the insulation film 14 on either one of the primary surfaces of the substrate 12. The insulation film 14 may be formed using arbitrarily an appropriate technique, such as application and thermal oxidation, depending on a material.

Next, the supporting substrate 20 is prepared. The supporting substrate 20 is a parallel-plate state of substrate (thin film) having two-sides of primary surfaces facing each other. Before preparing the supporting substrate 20, a substrate may be prepared so that one of the primary surfaces of the supporting substrate 20 is provided in advance with a thin film made of an electrically conductive material such as an indium tin oxide that may be a material for an electrode.

When the supporting substrate 20 is not provided with a thin film made of an electrically conductive material, a thin film made of an electrically conductive material is formed on one of the primary surfaces of the supporting substrate 20 by using arbitrarily an appropriate method. Next, the thin film made of an electrically conductive material is patterned. The thin film made from an electrically conductive material is patterned by using arbitrarily an appropriate method such as a photolithography process and an etching process, and thus the first electrode 32 is formed.

Next, the first electrical charge transport layer 42 is formed on the supporting substrate 20 provided with the first electrode 32, by using an appropriate method depending on a material arbitrarily.

Next, the active layer 50 is formed on the first electrical charge transport layer 42 according to an ordinary method. The active layer 50 may be formed by an application method such as spin coating, in which a coating fluid obtained by mixing a solvent and an appropriate material for an active layer is applied.

Next, the second electrical charge transport layer 44 covering the active layer 50 is formed by using arbitrarily an appropriate technique depending on a material.

Further, the second electrode 34 is formed on the second electrical charge transport layer 44. The second electrode 34 may be formed by using a film formation method using a solution such as a coating fluid. The second electrode 34 may be formed by using arbitrarily a well-known and appropriate method such as evaporation.

As described above, the first electrical charge transport layer 42, the active layer 50, the second electrical charge transport layer 44, and the second electrode 34 may be formed by, placing a layer formed by applying a coating fluid of a solution under an appropriate condition such as the nitrogen gas atmosphere and drying it at a condition appropriate for both a material and a solvent.

Examples of the film formation method may include application methods such as, spin coating, casting, micro gravure coating, gravure coating, bar coating, roll coating, wire bar coating, dip coating, spray coating, screen printing, gravure printing, flexo printing, offset printing, inkjet printing, dispenser printing, nozzle coating and capillary coating, and among them, spin coating, flexo printing, gravure printing, inkjet printing, and dispenser printing are preferred.

A solvent used in the film formation methods using a solution is not limited as long as the solvent can dissolve a material.

Examples of such a solvent may include: an unsaturated hydrocarbon solvent such as toluene, xylene, mesitylene, tetralin, decalin, bicyclohexyl, butylbenzene, sec-butylbenzene and tert-butylbenzene; a halogenated saturated hydrocarbon solvent such as carbon tetrachloride, chloroform, dichloromethane, dichloroethane, chlorobutane, bromobutane, chloropentane, bromopentane, chlorohexane, bromohexane, chlorocyclohexane and bromocyclohexane; a halogenated unsaturated hydrocarbon solvent such as chlorobenzene, dichlorobenzene, and trichlorobenzene; an ether solvent such as tetrahydrofuran and tetrahydropyran.

The layer formed by an application method may be placed under an arbitrary appropriate condition such as the nitrogen gas atmosphere and dried at a condition appropriate for both the material and the solvent, thereby being completed as a functional layer having a certain function.

Next, the second electrode 34 and the insulation film stacked substrate 10 are joined. The joining step is performed by joining the insulation film 14 of the insulation film stacked substrate 10 to the second electrode 34 by using a sealant (an adhesive) such as epoxy resin and forming the sealing layer 60 placed between the second electrode 34 and the insulation film 14.

The joining step may be performed by supplying a sealant material to an exposed surface of the second electrode 34 and/or an exposed surface of the insulation film 14, sticking the second electrode 34 and the insulation film stacked substrate 10, and then performing an arbitrary appropriate curing treatment such as pressurizing and heating to the provided sealant material.

By performing the above steps, an organic thin film solar cell may be manufactured.

### Second Embodiment

<Organic thin film solar cell>

The structure of an organic thin film solar cell of the second embodiment is explained referring to FIG. 3. With regard to the same structures as those of the first embodiment, the same numerals are given to the same components as those described in the first embodiment and a detailed description thereof may be omitted.

FIG. 3 is a schematic cross sectional view illustrating an example of a structure of an organic thin film solar cell of the second embodiment.

An organic thin film solar cell of the second embodiment is an example of a structure in which the insulation film stacked substrate 10 comprising the substrate 12 and the insulation film 14 stacked on the substrate 12 is made as a supporting substrate.

When using a high temperature step such as evaporation for forming the first electrode 32, the first electrical charge transport layer 42, the active layer 50 and the second electrical charge transport layer 44, heat resistance is required for an insulation film 14 of the second embodiment.

As illustrated in FIG. 3, the organic thin film solar cell is provided with a pair of electrodes of a first electrode 32 and a second electrode 34 and an active layer 50 placed between the pair of electrodes.

At least one electrode, which is one of the pair of electrodes, existing at a side from which light enters is a transparent or translucent electrode through which incident light (solar light) having a desired wavelength can pass.

Polarities of the first electrode 32 and the second electrode 34 may be an appropriate polarity that is selected arbitrarily corresponding to a structure of the cell, and therefore, it may be that the first electrode 32 may be a cathode and the second electrode 34 may be an anode.

The organic thin film solar cell is usually formed on a substrate. That is, a layered structure comprising the first electrode 32, the active layer 50, and the second electrode 34 is provided on the insulation film stacked substrate 10 comprising the substrate 12 and the insulation film 14 stacked on the substrate 12.

The insulation film stacked substrate 10 is usually nontransparent. Therefore, the sealing substrate 20, which is provided at an opposite side to the insulation film stacked substrate 10 so that the active layer 50 is sandwiched, is usually a transparent substrate.

A material for the sealing substrate 20 may be anything, as long as the material is not chemically changed during forming an electrode and forming a layer comprising an organic compound. Examples of a material for the sealing substrate 20 may include a glass, a plastic, a macromolecule film, and silicon.

When the insulation film stacked substrate 10 may be transparent, a nontransparent substrate may be used as the sealing substrate 20.

The active layer 50 is placed between the first electrode 32 and the second electrode 34. The active layer 50 of the second embodiment is a bulk hetero type of organic layer (a functional layer) in which an electron-acceptor compound (an n-type semiconductor material) and an electron donor compound (a p-type semiconductor material) are mixed and included.

As described above, the active layer 50 of the photovoltaic cell 10 comprises an electron donor compound and an electron-acceptor compound.

In the second embodiment, the active layer 50, that is a single active layer in which an electron-accepting compound and an electron donating compound are mixed to become a bulk hetero type, is explained. Or, the active layer 50 may be a structure comprising multiple layers; for example, it may be a hetero junction type in which an electron-acceptor layer comprising an electron-acceptor compound such as a fullerene derivative and an electron-donor layer comprising an electron-donor compound such as P3HT are joined.

In the organic thin film solar cell, an additional intermediate layer other than the active layer may be provided between at least either one of the first electrode 32 and the second electrode 34 and the active layer 50 as one means for improving the photovoltaic conversion efficiency.

Examples of the additional layer may include an electrical charge transport layer (hole transport layer, electron transport layer) that transports holes or electrons.

A structure of the organic thin film solar cell is explained more specifically. The first electrode 32 is provided on the insulation film 14 of the insulation film stacked substrate 10. In other words, an organic thin film solar cell is provided with the insulation film stacked substrate 10 in which the insulation film 14 is provided adjacent to either one of a pair of electrodes, for example, the first electrode 32 in the present example of structure.

The first electrical charge transport layer 42 is provided on the first electrode 32. The first electrical charge transport layer 42 is a hole transport layer when the first electrode 32 is an anode, and is an electron transport layer when the first electrode 32 is a cathode.

The active layer 50 is provided on the first electrical charge transport layer 42. The second electrical charge transport layer 44 is provided on the active layer 50. The second electrical charge transport layer 44 is an electron transport layer when the first electrode 32 is an anode, and is a hole transport layer when the first electrode 32 is a cathode. The second electrode 34 is provided on the second electrical charge transport layer 44.

The sealing layer 60 is provided on the second electrode 34. Through this sealing layer 60, the sealing substrate 20 is joined to an exposed surface of the second electrode 34.

The sealing layer 60 may be formed on an entire surface of the second electrode 34, or may be formed on a partial area of the surface of the second electrode 34.

A material for the supporting substrate 20 may be anything, as long as the material is not chemically changed during forming an electrode and forming a layer comprising an organic compound. Examples of a material of the substrate 20 may include a glass, a plastic, a macromolecule film, and silicon. The substrate 20 is provided so that, one of the primary surfaces thereof is joined to the second electrode 34 through the sealing layer 60, and another of the primary surfaces is exposed to an external environment.

The sealing layer 60 may be formed by using any well known and appropriate material with taking into consideration adhesiveness, heat resistance, and barrier properties against such as moisture and oxygen. Examples of a material of the sealing layer 60 may include a sealant or an adhesive made from epoxy resin.

According to an organic thin film solar cell of the second embodiment, because a substrate obtained from a material excellent in thermal conductivity and heat dissipation is provided, an increase of the temperature of the organic thin film solar cell can be suppressed. Therefore, deterioration in properties of the organic thin film solar cell due to an increase of the temperature of the organic thin film solar cell can be suppressed effectively.

<Manufacturing Method>

A method for manufacturing the organic thin film solar cell is explained referring to FIG. 3.

The method for manufacturing the organic thin film solar cell of the second embodiment is a method for manufacturing an organic thin film solar cell comprising a pair of electrodes of the first electrode 32 and the second electrode 34 and the active layer 50 placed between the pair of electrodes, the method comprising: preparing a insulation film stacked substrate 10 comprising a substrate 12 comprising a metal or an alloy and an insulation film 14 formed on the substrate 12; forming a first electrode 32 on the insulation film 14 of the insulation film stacked substrate 10; forming a first electrical charge transport layer 42 on the first electrode 32 provided on the insulation film stacked substrate 10; forming an active layer 50 on the first electrical charge transport layer 42; forming a second electrical charge transport layer 44 on the active layer 50; forming a second electrode 34 on the second electrical charge transport layer 44; and forming the sealing layer 60 placed between the second electrode 34 and a sealing substrate 20 by joining the second electrode 34 and the sealing substrate 20 using a sealant.

For manufacturing an organic thin film solar cell, at first, the insulation film stacked substrate 10 is prepared.

The insulation film stacked substrate 10 is formed by forming the insulation film 14 on one of primary surfaces of the substrate 12. The insulation film 14 is preferably formed by using arbitrarily an appropriate technique, such as application and thermal oxidation, depending on a material.

Next, the first electrode 32 is formed on the insulation film 14 of the insulation film stacked substrate 10.

The first electrode 32 may be formed, for example, by forming a thin film of an electrically conductive material on the insulation film 14 by using arbitrarily an appropriate method and then patterning the thin film of the electrically conductive material by using arbitrarily an appropriate method such as a photolithography process and an etching process.

Next, the first electrical charge transport layer 42 is formed on an entire surface of the substrate 20 on which the first electrode 32 is formed, by using arbitrarily an appropriate technique depending on a material.

Next, the active layer 50 is formed on the first electrical charge transport layer 42 according to an ordinary method. The active layer 50 may be formed by using an application method such as spin coating, in which a coating fluid obtained by mixing a solvent and an appropriate material for an active layer is applied.

Next, the second electrical charge transport layer 44 covering the active layer 50 is formed by using an arbitrarily an appropriate technique depending on a material.

Further, the second electrode 34 is formed on the second electrical charge transport layer 44. The second electrode 34 may be formed by using a film formation method using a solution such as a coating fluid. The second electrode 34 may be formed by using arbitrarily a well known and appropriate method such as evaporation.

As described above, the first electrical charge transport layer 42, the active layer 50, the second electrical charge transport layer 44, and the second electrode 34 may be formed by, placing a layer formed by applying a coating fluid of a solution under an appropriate condition such as the nitrogen gas atmosphere and drying it at a condition appropriate for both a material and a solvent.

Next, the second electrode 34 and the sealing substrate 20 are joined. The joining step is performed by joining the sealing substrate 20 to the second electrode 34 by using a sealant (an adhesive) such as epoxy resin and forming the sealing layer 60 placed between the second electrode 34 and the sealing substrate 20.

The joining step may be performed, by supplying a sealant material to one of primary surfaces of the substrate 20 and/or an exposed surface of the insulation film 14, sticking the second electrode 34 and the substrate 20 and then providing arbitrarily an appropriate curing treatment such as pressurizing and heating to the provided sealant material.

By performing the above steps, the organic thin film solar cell may be manufactured.

In a method for manufacturing the organic thin film solar cell of the second embodiment, a layered structure comprising a first electrical charge transport layer, an active layer, a second electrical charge transport layer, and a second electrode is formed on an insulation film stacked substrate. The insulation film stacked substrate usually has higher heat resistance as compared with a material such as resin film used as a substrate. Therefore, by using an insulation film stacked substrate as a supporting substrate, a film formation step at higher temperature can be adopted, and accordingly a wide range of choices of a material for a functional layer such as an electrode, an electrical charge transport layer, and an active layer formed on the insulation film stacked substrate can be obtained. As the result, the organic thin film solar cell having further high performance can be pursued and achieved.

<Operation>

An operation mechanism of the organic thin film solar cell is explained briefly. Energy of light incident passed through a transparent or translucent electrode and entered into an active layer is absorbed by an electron-acceptor compound and/or an electron donor compound, and generates excitons in which an electron and a hole are bound. When the generated exciton moves and reaches a heterozygous interface at which the electron-acceptor compound and the electron donor compound are joined, the electron and the hole are separated due to the differences in a HOMO energy and a LUMO energy of the respective compounds at the interface, and electrical charges (electrons and holes) that can move independently generate. The generated electrical charges move to respective electrodes (cathode, anode), and thereby electrical energy (current) can be extracted to the outside of the cell.

<Applications>

According to the organic thin film solar cell manufactured by the manufacturing method of the present invention, because light such as sunlight can pass through the first electrode and/or the second electrode that are(is) a transparent or translucent electrode and can enters into the cell, a photovoltaic power generates between the electrodes, and thus the cell of the present invention can work as a solar cell. By collecting multiple organic thin film solar cells, it can be used as an organic thin film solar cell module.

### EXAMPLES

### Example 1

A substrate made of stainless steel (SUS304) was prepared and degreased with acetone. One of the primary surfaces of the substrate was applied with polysilazane (manufactured by AZ Electronics; trade name, AQUAMICA (NL120A-20)). Then, the substrate was heated at 120° C. for 30 minutes, and thus an insulation film stacked substrate in which an insulation film (silicon oxide film) formed on the substrate was obtained.

A glass substrate (a first substrate), on which a thin ITO film having a thickness of 150 nm was provided, was obtained by sputtering, and this was cleaned with acetone. Then, an UV ozone cleansing treatment was performed for 15 minutes by using an ultraviolet ozone irradiation device equipped with a low pressure mercury vapor lamp (manufactured by TECHNOVISION, INC.; TYPE, UV-312), thereby an ITO electrode (a first electrode) having a clean surface was prepared.

Next, a layer of PEDOT (manufactured by H.C. Starck GmbH; trade name, Baytron P AI4083, lot. HCD0701019)(a first electrical charge transport layer) was applied to the surface of the ITO electrode by spin coating.

Then, the layer was dried at 150° C. for 30 minutes in an atmosphere. An electron-donor compound of poly(3-hexylthiophene) (P3HT) (manufactured by Merck; trade name, lisicon SP001, lot. EF431002) and an electron-acceptor compound of PCBM (manufactured by Frontier Carbon Corporation; trade name, E100, lot. 7B0168-A) as a fullerene derivative were added in an o-dichlorobenzene solvent so that P3HT is 1.5 wt% and PCBM is 2 wt%, followed by stirring at 70° C. for 2 hours and then being filtered through a filter having a pore size of 0.2 and thereby a coating fluid was prepared.

On the PEDOT layer, the coating fluid was applied by spin coating, followed by a heat treatment at 150° C. for 3 minutes in the atmosphere of nitrogen gas, and thus an active layer film was obtained. After the heat treatment, a thickness of the active layer film was about 100 nm. Then, by using a vacuum evaporator, a LiF layer (a second electrical charge transport layer) having a thickness of 2 nm and an Al layer (a second electrode) having a thickness of 70 nm were evaporated respectively in this order. All degrees of vacuum during the evaporation were 1×10⁻⁴ Pa to 9×10⁻⁴ Pa.

Then, in the atmosphere of nitrogen gas, a sealing layer was formed on the Al layer using a sealant made from an epoxy resin, accompanied by adhering to (joining) an insulation film stacked substrate by this sealing layer. A shape of the organic thin film solar cell is a 2 mm×2 mm square.

### Example 2

The organic thin film solar cell was prepared in the same manner as in Example 1 except that a copper substrate was used instead of a stainless steel substrate.

### Comparative Example 1

The organic thin film solar cell was prepared in the same manner as in Example 1 except that the substrate joined on the Al layer was a glass substrate.

### Evaluation

With regard to the prepared organic thin film solar cells, by using a solar simulator (manufactured by YAMASHITA DENSO, Trade name YSS-80), continuous irradiation of light was performed at an irradiance of 100 mW/cm² through an AM1.5G filter, and then temperatures of the organic thin film solar cells before and after irradiation were measured with a thermocouple.

### Result

The temperature of the organic thin film solar cell using the glass substrate of Comparative Example 1 was 40±2° C. after the irradiation. On the other hand, the respective temperatures of the organic thin film solar cells of Example 1 and Example 2 using the insulation film stacked substrate were both 36±2° C. after the irradiation. Therefore, the use of an insulation film stacked substrate of the present invention reduced a temperature increment of the organic thin film solar cell before and after irradiation.

### INDUSTRIAL APPLICABILITY

The present invention is useful for providing an organic thin film solar cell.

1. An organic thin film solar cell comprising:
a pair of electrodes of a first electrode and a second electrode;
an active layer placed between the pair of electrodes;
an insulation film stacked substrate comprising, a substrate comprising a metal or an alloy having heat conductivity higher than 10 W/m.K and lower than 500 W/m.K, and an insulation film provided on the substrate; and
a sealing layer placed between the insulation film of the insulation film stacked substrate and either one of the pair of electrodes.

2. An organic thin film solar cell comprising:
a pair of electrodes of a first electrode and a second electrode;
an active layer placed between the pair of electrodes; and
an insulation film stacked substrate comprising, a substrate comprising a metal or an alloy having heat conductivity higher than 10 W/m.K and lower than 500 W/m.K, and an insulation film provided on the substrate, the insulation film being provided adjacent to either one of the pair of electrodes.

3. The organic thin film solar cell according to claim 1, wherein the metal is aluminum or copper.

4. The organic thin film solar cell according to claim 1, wherein the alloy is stainless steel.

5. The organic thin film solar cell according to claim 1, wherein the insulation film is composed of an insulative inorganic compound or an insulative organic compound.

6. The organic thin film solar cell according to claim 5, wherein the insulative inorganic compound is an oxide, a nitride, or a carbide.

7. The organic thin film solar cell according to claim 5, wherein the insulative inorganic compound is one selected from the group consisting of silicon, aluminum, and zirconium.

8. The organic thin film solar cell according to claim 5, wherein the insulative organic compound is a polyimide.

9. The organic thin film solar cell according to claim 2, wherein the insulation film stacked substrate is a supporting substrate.

10. The organic thin film solar cell according to claim 1, wherein the insulation film stacked substrate is a sealing substrate.

11. A method for manufacturing an organic thin film solar cell, the method comprising the steps of:
preparing an insulation film stacked substrate comprising, a substrate comprising a metal or an alloy, and an insulation film formed on the substrate;
forming a first electrode on a supporting substrate;
forming a first electrical charge transport layer on the substrate on which the first electrode is formed;
forming an active layer on the first electrical charge transport layer;
forming a second electrical charge transport layer on the active layer;
forming a second electrode on the second electrical charge transport layer;
forming a sealing layer placed between the second electrode and the insulation film by joining the second electrode to the insulation film of the insulation film stacked substrate by using a sealant.

12. A method for manufacturing an organic thin film solar cell, the method comprising the steps of:
preparing an insulation film stacked substrate comprising, a substrate comprising a metal or an alloy, and an insulation film formed on the substrate;
forming a first electrode on the insulation film of the insulation film stacked substrate;
forming a first electrical charge transport layer on the insulation film stacked substrate on which the first electrode is formed;
forming an active layer on the first electrical charge transport layer;
forming a second electrical charge transport layer on the active layer;
forming a second electrode on the second electrical charge transport layer; and
forming a sealing layer placed between the second electrode and a sealing substrate by joining the second electrode to the sealing substrate by using a sealant.
